(19) United States
(12) Patent Application Publication
(10) Pub. No.: US 2008/0094806 A1
(43) Pub. Date: Apr. 24, 2008

(54) Electrohydraulic control device

(75) Inventors: Marco Grethel, Buhlertal (DE); Manfred Homm, Buhl-Neusatz (DE)

Correspondence Address: ALFRED J MANGELS, 4729 CORNELL ROAD, CINCINNATI, OH, 452412433, US

(73) Assignee: LuK Lamellen und Kupplungsbau Beteiligungs KG, Buhl (DE)

(21) Appl. No.: 11/906,779

(22) Filed: Oct. 3, 2007

Related U.S. Application Data
(63) Continuation of application No. PCT/DE2006/000417, filed on Mar. 9, 2006.

(30) Foreign Application Priority Data
Apr. 7, 2005 (DE) 10 2005 015 968.0

(51) Int. Cl. H05K 5/02

(52) U.S. Cl. 361/728

(57) ABSTRACT

An electrohydraulic control device that includes at least one hydraulic actuator element, at least one sensor element, and at least one electronic control unit. The actuator element and the sensor element are combined in a hydraulically sealed hydraulic control device that is separated from the electronic control unit and that has a common power and signal terminal for connecting lines to connect the actuator element and the sensor element to the electronic control unit.

### CROSS-REFERENCE TO RELATED APPLICATION

This is a continuation of International Application Ser. No. PCT/DE2006/000417, with an international filing date of Mar. 9, 2006, and designating the United States, the entire contents of which are hereby incorporated by reference to the same extent as if fully rewritten.

### BACKGROUND OF THE INVENTION

1. Field of the Invention

The present invention relates to an electrohydraulic control device that includes at least one electrical actuation element, at least one sensor element, and at least one electronic control unit.

2. Description of the Related Art

In conventional hydraulic control devices the electronic control unit is integrated into the electrohydraulic control device.

An object of the present invention is to provide a reliably functioning and inexpensively producible electrohydraulic control device that includes at least one electrical actuation element, at least one sensor element, and at least one electronic control unit.

### SUMMARY OF THE INVENTION

The object is achieved with an electrohydraulic control device that includes at least one electrical actuation element, at least one sensor element, and at least one electronic control unit, in which the actuation element and the sensor element are combined in a hydraulically sealed hydraulic control unit that is separate from the electronic control unit. The hydraulic control unit has a common power and signal connection for connecting lines that connect the actuation element and the sensor element to the electronic control unit.

In conjunction with the present invention, it has been found that it is better in terms of the manufacturing costs not to accommodate the electronic control unit in a common housing together with hydraulic actuation elements and sensor elements. The separate electronic control unit provides the advantage that expensive hydraulic encapsulation of the electronic control unit can be dispensed with. That is especially true when the electronic control unit is situated at a location in a motor vehicle that is protected from environmental influences, for example in the interior of the vehicle. The hydraulic control unit can be mounted directly on a hydraulic component that is to be controlled, for example. A common power and signal connection provides a central connection point that is simple to seal. The actuation element is preferably an electromagnet that serves to operate a hydraulic valve.

Preferably, the hydraulic control unit has at least one hydraulic connection arrangement that serves to connect the hydraulic control unit to a hydraulic component. The electrical actuation elements and the sensor elements can be connected to the common power and signal connection in the interior of the electronic control device with the help of flexible lines, through simple contacts such as plug contacts, for example. That makes it possible to forego complicated individual protection of the actuation and sensor elements. According to one aspect of the present invention, the impermeability of the contacts from inside to outside and vice versa only needs to be ensured at the common power and signal connection.

A preferred exemplary embodiment of the control device is characterized in that the hydraulic control unit includes at least one conductor unit of plastic material, in which the connecting lines are embedded. Preferably, the connecting lines are formed of a stamped grid pattern that is embedded in plastic or is spray-coated with plastic.

Another preferred exemplary embodiment of the control device is characterized in that the common power and signal connection is formed as a single piece with the conductor unit. Preferably, the power and signal connection includes a plug made of plastic that is sprayed onto the conductor unit. In addition, the connecting lines are spray-coated with plastic in the area of the power and signal connection, in order to seal the interface between the connecting lines and the plug.

Another preferred exemplary embodiment of the control device is characterized in that at least one sensor element is integrated into the conductor unit. Preferably, the sensor element is spray-coated with plastic in order to ensure a reliable seal against a hydraulic medium that is contained in the hydraulic control unit.

Another preferred exemplary embodiment of the control device is characterized in that at least one Hall sensor and/or at least one pressure sensor is integrated into the conductor unit. The Hall sensor is used to monitor the position of a valve actuator, for example. The pressure sensor is used to detect the pressure of a hydraulic medium that is contained at a particular location in the hydraulic control unit, for example.

Another preferred exemplary embodiment of the control device is characterized in that at least one plug connection element is integrated into the conductor unit. The plug connection element is used to connect an electromagnet for example.

Another preferred exemplary embodiment of the control device is characterized in that the hydraulic control unit has a protective cover of plastic. The protective cover is used to seal the hydraulic control unit from the environment.

Another preferred exemplary embodiment of the control device is characterized in that the common power and signal connection is formed as a single piece with the protective cover. Preferably, the power and signal connection includes a plug made of plastic that is sprayed onto the protective cover. In addition, the connecting lines are spray-coated with plastic in order to seal the interface between the connecting lines and the plug.

Another preferred exemplary embodiment of the control device is characterized in that the hydraulic control unit includes at least one valve. The valve includes a valve spool, for example, which is movable back and forth in a corresponding guide channel in the hydraulic control unit against the biasing force of a valve spring.

Another preferred exemplary embodiment of the control device is characterized in that the hydraulic control unit includes at least one control plate. Preferably, the control plate is formed in labyrinth style from a die-cast aluminum housing part that includes channels and connections, in particular hydraulic connections, for hydraulic valves. Valve spools and electromagnets of hydraulic valves can be accommodated in the control plate or in an additional control plate.

### BRIEF DESCRIPTION OF THE DRAWINGS

Additional advantages, characteristics, and details of the invention are evident from the following description, in which two exemplary embodiments are described in detail with reference to the drawings. The characteristics mentioned in the claims and in the description may be essential to the invention individually by themselves or in any combination. The figures show the following:

FIG. 1: a schematic representation, in cross section, of an electrohydraulic control device in accordance with a first exemplary embodiment of the present invention, and

FIG. 2: a schematic representation, in cross section, of an electrohydraulic control device in accordance with a second exemplary embodiment of the present invention.

### DESCRIPTION OF THE PREFERRED EMBODIMENTS

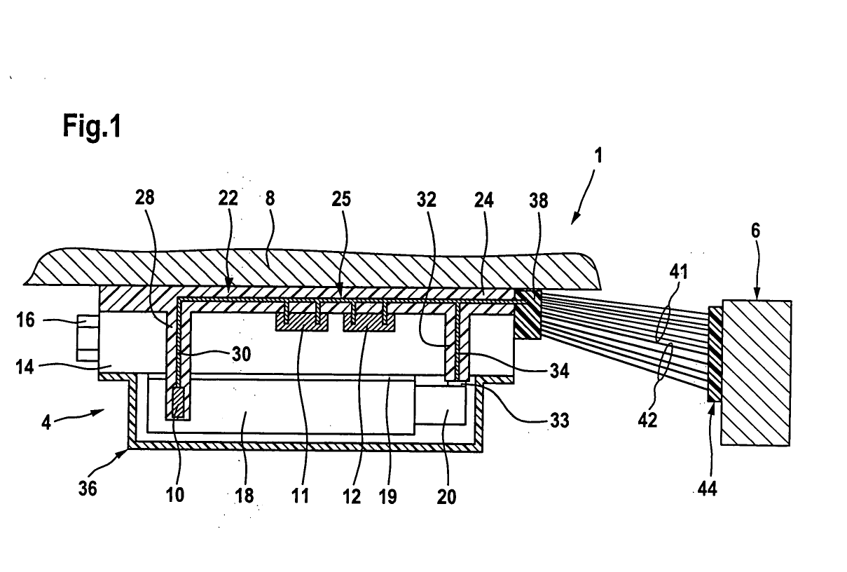

An electrohydraulic control device 1 is represented schematically in cross section in FIG. 1. The electrohydraulic control device 1 includes a hydraulic control unit 4 and an electronic control unit 6. The hydraulic control unit 4 is mounted on a mounting surface 8 of a motor vehicle, on or in the vicinity of a hydraulic component (not shown) that is to be controlled. The hydraulic component can be an automatic transmission of a motor vehicle, for example. But it can also be an active roll stabilization system, for example. In accordance with the present invention, electronic control unit 6 is accommodated separately from hydraulic control unit 4, and intentionally at a different location on the motor vehicle where electronic control unit 6 is not subjected to environmental influences, or at least not so severely. Expensive encapsulation of electronic control unit 6 can therefore be eliminated.

Hydraulic control unit 4 contains a Hall sensor 10 and two pressure sensors 11, 12. Hall sensor 10 serves to detect the position or location of a valve actuator that is movably incorporated in hydraulic control unit 4. Pressure sensors 11, 12 serve to detect the pressure of a hydraulic medium at various locations for electronic control unit 6.

Hydraulic control unit 4 includes a first control plate 14, which is formed in labyrinth style by a die-cast aluminum housing part. The first control plate 14 contains channels and hydraulic connections, which are combined in a common hydraulic connection 16. A second control plate 18 is separated from first control plate 14 by an intermediate plate 19. Second control plate 18 guides a valve spool (not shown) so that it can move back and forth; its position is detected by Hall sensor 10. The valve spool is operated by an electromagnet 20, which is also referred to as an actuator or actuator element. Electromagnet 20 is also accommodated in second control plate 18.

Hydraulic control unit 4 further includes a conducting device 22, which is made of plastic 24. Embedded in the plastic 24 are a large number of power transmission and signal transmission lines 25. The power transmission and signal transmission lines 25 are preferably formed of stamped grids that are spray-coated with the plastic material 24. Conducting device 22 has a first conductor arm 28, which extends from conducting device 22 through first control plate 14 into second control plate 18. Hall sensor 10 is contained in the free end of first conductor arm 28. Emerging from Hall sensor 10 is a signal line 30, which is embedded in first conductor arm 28. Furthermore, a second conductor arm 32 extends from conductor device 22, and likewise extends through the first control plate 14 into the region of the second control plate 18. At the free end of second conductor arm 32 a plug contact 33 for connecting electromagnet 20 is provided, which is accommodated in second control plate 18 or mounted on it. A power line 34 extends from plug contact 33 through conductor arm 32 into conductor device 22.

Conductor device 22 and first control plate 14 are pressure sealed toward the outside. Second control plate 18 with electromagnet 20 is sealed against the environment by a protective cover 36 made of plastic.

In addition, a central connecting plug 38 of plastic is injected onto conductor device 22. The many power transmission and signal transmission lines 25 are routed out of the hydraulic control device 4 through central connecting plug 38. A plurality of cable conductors for sensor elements are indicated by reference numeral 41. Cable conductors for electromagnets are designated by reference numeral 42. Cable conductors 41, 42 are brought together in a common connection plug 44 of electronic control unit 6.

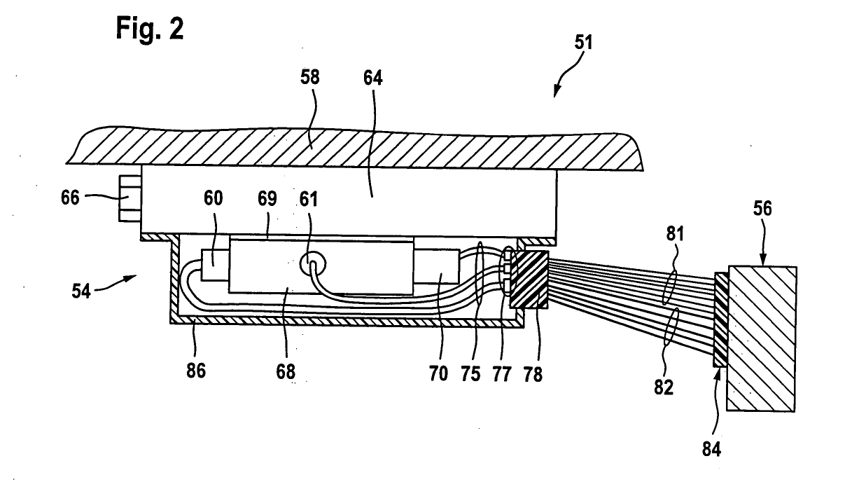

Another embodiment of an electrohydraulic control device in accordance with the present invention is shown schematically in FIG. 2. Electrohydraulic control device 51 includes a hydraulic control unit 54, which is executed and situated separately from an electronic control unit 56. Hydraulic control unit 54 is attached to a mounting surface 58 of a motor vehicle. Electronic control unit 56 is accommodated at a different location in the motor vehicle, where it is not subjected to environmental influences, or not such severe ones.

Hydraulic control unit 54 includes two sensors 60 and 61. Attached directly at the mounting surface 58 of the motor vehicle is a first control plate 64, which is constructed to be pressure sealed toward the outside and has a common hydraulic connection 66. Second control plate 68 is mounted on first control plate 64, with an intermediate plate 69 inserted in between.

Guided in second control plate 68 is a valve spool (not shown) of a hydraulic valve, which is operable by an electromagnet 70. Sensors 60 and 61 are mounted on second control plate 68 or integrated into it. Power and signal transmission conductors 75 that extend from electromagnet 70 and from sensors 60 and 61, are routed past second control plate 68 and are connected to a central connecting plug 78 through internal contacts 77. Cable conductors for sensors, extending from central connecting plug 78, are indicated by reference numeral 81. Reference numeral 82 designates cable conductors for electromagnets, which cable conductors also extend from central connecting plug 78. Cable conductors 81 and 82 are connected to electronic control unit 56 with the help of a common connecting plug 84.

Second control plate 68, with the power and signal transmission conductors 75 extending outside of second control plate 68, is sealed from the environment by a protective cover 86 made of plastic. That ensures that no hydraulic medium will get into the environment, even in the event of leakage.

1. An electrohydraulic control device comprising:
a) at least one electrical actuator element,
b) at least one sensor element (10-12; 60, 61),
c) at least one electronic control unit,
wherein the at least one electrical actuator element and the at least one sensor element are housed in a hydraulic control unit that is separate from the electronic control unit and is sealed to prevent hydraulic fluid leakage, which control device includes a common power and signal connector for conductor lines that connect the at least one electrical actuator element and the at least one sensor element with the electronic control unit.

2. A control device in accordance with claim 1, wherein the hydraulic control unit includes at least one conductor device of plastic material, in which the conductor lines are embedded.

3. A control device in accordance with claim 2, wherein the common power and signal connection is formed in a single piece with the conductor device.

4. A control device in accordance with claim 2, wherein at least one sensor element is integrated into the conductor device.

5. A control device in accordance with claim 2, wherein at least one of a Hall sensor and at least one pressure sensor is integrated into the conductor device.

6. A control device in accordance with claim 2, including at least one plug connection element that is integrated into the conductor device.

7. A control device in accordance with claim 1, wherein the hydraulic control unit includes a protective cover made of plastic.

8. A control device in accordance with claim 7, wherein the common power and signal connection is formed in a single piece with the protective cover.

9. A control device in accordance with claim 1, wherein the hydraulic control unit includes at least one hydraulic valve.

10. A control device in accordance with claim 1, wherein the hydraulic control unit includes at least one control plate.
